(19) United States
(12) Patent Application Publication
(10) Pub. No.: US 2012/0261581 A1
(43) Pub. Date: Oct. 18, 2012

(54) METHOD FOR MANUFACTURING DETECTOR, RADIATION DETECTION APPARATUS INCLUDING DETECTOR MANUFACTURED THEREBY, AND RADIATION DETECTION SYSTEM

(75) Inventors: Kentaro Fujiyoshi, Kumagaya-shi (JP); Chiori Mochizuki, Sagamihara-shi (JP); Minoru Watanabe, Honjo-shi (JP); Keigo Yokoyama, Honjo-shi (JP); Masato Ofuji, Honjo-shi (JP); Jun Kawanabe, Kodama-gun (JP); Hiroshi Wayama, Honjo-shi (JP)

(73) Assignee: CANON KABUSHIKI KAISHA, Tokyo (JP)

(21) Appl. No.: 13/444,560

(22) Filed: Apr. 11, 2012

(30) Foreign Application Priority Data
Apr. 18, 2011 (JP) 2011-092151

(51) Int. Cl. G01T 1/20; H01L 31/18

(52) U.S. Cl. 250/361 R; 438/98; 257/E31.126

(57) ABSTRACT

A method is provided for manufacturing a high-performance plane-type detector without the increase in cost or decrease in yield accompanying the increase in the number of masks. The method includes the first step of forming a first electrode and a control electrode from a first electroconductive film deposited on a substrate, the second step of depositing an insulating film and a semiconductor film in that order after the first step, the third step of depositing an impurity semiconductor film and a second electroconductive film in that order after the second step, and forming a common electrode wire and a first electroconductive member from the second electroconductive film, and the fourth step of forming with the same mask a second electrode and a second electroconductive member from a transparent electroconductive oxide film formed after the third step, and impurity semiconductor layers from the impurity semiconductor film.

### BACKGROUND OF THE INVENTION

1. Field of the Invention

The present invention relates to a method for manufacturing a detector that can be applied to medical image diagnostic apparatuses, nondestructive inspection apparatuses and analyzers using radiation, and relates to a detector, a radiation detection apparatus and a radiation detection system.

2. Description of the Related Art

In recent years, thin-film semiconductor manufacturing techniques have been used for detectors and radiation detection apparatuses that use a pixel array including switching elements such as thin-film transistors (TFTs) and conversion elements such as photoelectric conversion elements.

In some of such detectors, the photoelectric conversion element and TFT of each pixel are formed on a substrate in a common process (see U.S. Pat. No. 6,682,960), and this type of detector hereinafter will be referred to as plane-type detector. U.S. Pat. No. 6,682,960 discloses the following techniques. It is performed through the same mask to form a metal layer such as Al (aluminum) layer that will be formed into source and drain electrodes of the TFT and to remove an impurity semiconductor layer from the region that will act as the channel of the TFT. Then, a metal layer such as an Al layer of the photoelectric conversion element is etched through another mask to form the upper electrodes of the photoelectric conversion element. In order to reduce the resistance of the metal layer that will be formed into the source and drain electrodes, a 1 μm thick Al film is used as the metal layer.

In U.S. Pat. No. 6,682,960, the metal layer is a 1 μm thick Al film. From the viewpoint of reducing the resistance, the metal layer can be formed of metals such as Al and Cu (copper), which are advantageously used as a wiring material in semiconductor devices and have specific resistances of less than 3.0 μΩ·cm at 300 K, to a thickness of 0.5 to 1 μm. Since these metals are not passive, they can be easily corroded by water or a remaining component of an etchant used in a manufacturing process. Accordingly, it becomes important that the source and drain electrodes are covered with a moisture-resistant passivation film with sufficient coverage. An inorganic insulating film formed by depositing silicon nitride (SiN) or the like by CVD is used as the moisture-resistant passivation film. Since the inorganic insulating film formed by CVD is hard, it can be cracked by thermal expansion and thermal contraction accompanying heat treatment performed in the manufacturing process if it is formed to a small thickness. Accordingly, in order to cover the source and drain electrodes with an inorganic insulating film with sufficient coverage, the inorganic insulating film is formed to a thickness of 0.5 to 1 μm, equal to the thickness of the source and drain electrodes. However, hard inorganic insulating films have high stresses, and may cause the substrate to warp. It is therefore undesirable to form the inorganic insulating film to a large thickness. In addition, since it takes a long time to form a thick inorganic insulating film by vapor deposition such as CVD, throughput is reduced. This is disadvantageous in manufacturing cost.

In the above-cited U.S. Pat. No. 6,682,960, the upper electrode of the photoelectric conversion element is made of a metal layer. In order to uniformly apply a bias to the entire photoelectric conversion element, the impurity semiconductor layer of the photoelectric conversion element is covered widely with a metal layer. However, if the impurity semiconductor layer of the photoelectric conversion element is widely covered with a metal layer, the aperture ratio, which is a ratio of the area of the semiconductor layer into which light can enter to the surface area of the photoelectric conversion element, is reduced.

Furthermore, if the upper electrode of the photoelectric conversion element and the source and drain electrodes of the TFT are formed in different steps, the number of masks is increased. Accordingly, the yield can be reduced and the cost can be increased.

### SUMMARY OF THE INVENTION

Aspects of the present invention provide a method for manufacturing a detector including a photoelectric conversion element having a high aperture ratio and a corrosion-resistant TFT that are formed in a common process, without the increase in cost or decrease in yield accompanying the increase in the number of masks.

According to an aspect of the present invention, a method is provided for manufacturing a detector including a photoelectric conversion element that includes on a substrate, in this order from the substrate, a first electrode, an insulating layer, a semiconductor layer, an impurity semiconductor layer, and a second electrode to which a common electrode wire is electrically connected, and a thin film transistor that includes on the substrate, in this order from the substrate, a control electrode, an insulating layer, a semiconductor layer, an impurity semiconductor layer, and a first and a second main electrode including a first electroconductive member and a second electroconductive member. The method includes the first step of depositing a second electroconductive film containing a non-passive metal over the substrate so as to cover an impurity semiconductor film, and forming the first electroconductive member of the first and second main electrodes and the electrode wire from the second electroconductive film. The method also includes the second step of depositing a transparent electroconductive oxide film over the substrate so as to cover the impurity semiconductor film, the electrode wire and the first electroconductive member, forming the second electroconductive member of the first and second main electrodes and the second electrode from the transparent electroconductive oxide film, and forming the impurity semiconductor layer of the thin film transistor and the impurity semiconductor layer of the photoelectric conversion element from the impurity semiconductor film. The second electroconductive member, the second electrode, the impurity semiconductor layer of the thin film transistor, and the impurity semiconductor layer of the photoelectric conversion element are formed with the same mask in the second step, and the first electroconductive member and the electrode wire are formed with another mask in the first step.

Aspects of the present invention can provide a plane-type detector including a photoelectric conversion element having a high aperture ratio and a corrosion-resistant TFT that are formed in a common process, without increasing the cost or reducing the yield.

Further features of the present invention will become apparent from the following description of exemplary embodiments with reference to the attached drawings.

### BRIEF DESCRIPTION OF THE DRAWINGS

FIG. 1A is a plan view of a pixel of a detector according to a first embodiment of the present invention, and FIG. 1B is a sectional view taken along line A-A′ in FIG. 1A.

FIGS. 2A, 2C and 2E are schematic plan views of a mask pattern used in a method for manufacturing the detector according to the first embodiment, and FIGS. 2B, 2D and 2F are schematic sectional views of the detector in a step of the method.

FIGS. 3A, 3C and 3E are schematic plan views of a mask pattern used in aspects of the method, and FIGS. 3B, 3D and 3F are schematic sectional views of the detector in a step according to aspects of the method.

FIG. 4 is an equivalent circuit diagram of the detector of an embodiment of the invention. FIG. 5A is a plan view of a pixel of a detector according to a second embodiment of the present invention, and FIG. 5B is a sectional view taken along line VB-VB in FIG. 5A.

FIGS. 6A, 6C, 6E and 6G are schematic plan views of a mask pattern used in a method for manufacturing the detector according to the second embodiment, and FIGS. 6B, 6D, 6F and 6H are schematic sectional views of the detector in a step according to aspects of the method.

FIG. 7 is a conceptual representation of a radiation detection system including the detector according to an embodiment of the invention.

### DESCRIPTION OF THE EMBODIMENTS

Some embodiments of the present invention will be described in detail with reference to the drawings. The radiation mentioned herein includes beams produced from particles (including photons) emitted by radioactive decay, such as α rays, β rays, and γ rays, and beams having the same energy or more, such as X rays, corpuscular beams, and cosmic rays.

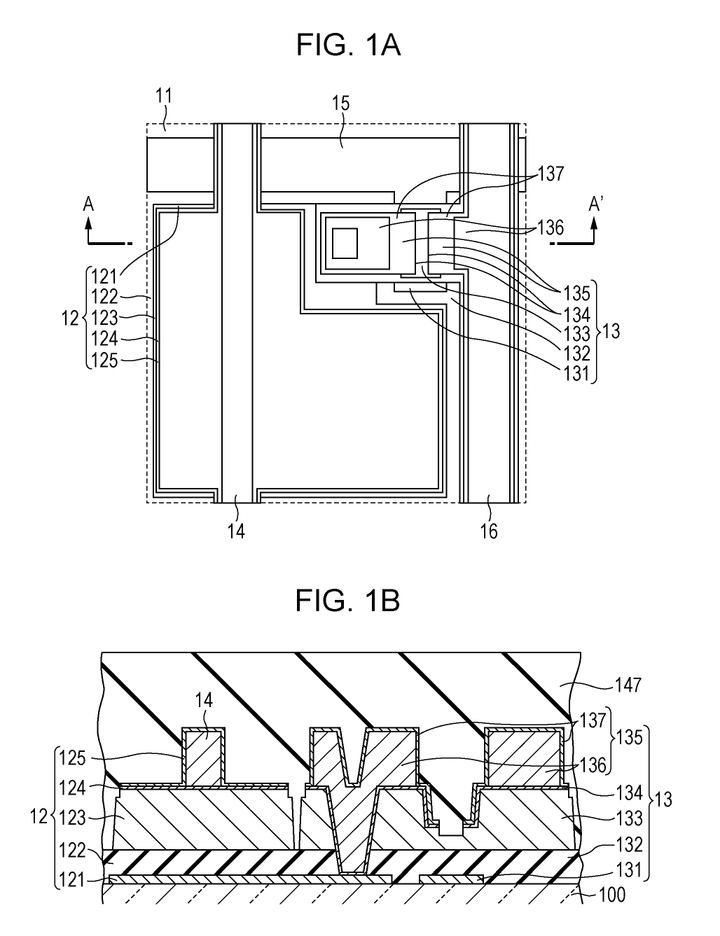

The structure of the pixel of a detector according to a first embodiment of the invention will first be described with reference to FIGS. 1A and 1B. FIG. 1A is a plan view of a pixel of the detector, and FIG. 1B is a sectional view taken along line A-A′ in FIG. 1A.

Each pixel 11 of the detector of an embodiment of the invention includes a photoelectric conversion element 12 that converts radiation or light into a charge, and a thin film transistor (TFT) 13, or a switching element, that outputs electrical signals according to the charge of the photoelectric conversion element 12. The photoelectric conversion element 12 has an MIS structure, which is the same layered structure as the TFT 13. The photoelectric conversion element 12 and TFT 13 are arranged side by side in the same plane on an insulating substrate 100, such as a glass substrate. The photoelectric conversion element 12 and TFT 13 are formed on the substrate 100 in a common process.

The photoelectric conversion element 12 includes on the substrate 100, in this order from the substrate, a first electrode 121, an insulating layer 122, a semiconductor layer 123, and an impurity semiconductor layer 124 having a higher impurity concentration than the semiconductor layer 123, and a second electrode 125. An electrode wire 14 of a metal such as Al is electrically connected to the second electrode 125 of the photoelectric conversion element 12. The second electrode 125 is made of a transparent electroconductive oxide such as ITO, and covers the entire surfaces of the impurity semiconductor layer 124 and the electrode wire 14, in the region of the photoelectric conversion element 12 in which the semiconductor layer 123 and the impurity semiconductor layer 124 are disposed. The second electrode 125 helps apply a uniform bias to the entirety of the photoelectric conversion element 12, and allows the photoelectric conversion element 12 to have a high aperture ratio.

The TFT 13 includes on the substrate 100, in this order from the substrate, a control electrode 131, an insulating layer 132, a semiconductor layer 133, and an impurity semiconductor layer 134 having a higher impurity concentration than the semiconductor layer 133, and a first and a second main electrode 135. The impurity semiconductor layer 134 is partially in contact with the first and second main electrodes 135, and the channel region of the TFT is defined between the portions of the semiconductor layer 133 in contact with the portions of the impurity semiconductor layer 134 in contact with the first and second main electrodes 135. The control electrode 131 is electrically connected to a control line 15. One of the first and second main electrodes 135 is electrically connected to the first electrode 121 of the photoelectric conversion element 12, and the other is electrically connected to a signal line 16. In the present embodiment, this electrode of the first and second main electrodes 135 is integrated with the signal line 16 using the same electroconductive layer, and serves as a part of the signal line 16. The signal line 16 and the first and second main electrodes 135 include a first electroconductive member 136 made of a metal such as Al and a second electroconductive member 137 made of a transparent electroconductive oxide such as ITO. The first electroconductive member 136 is covered with the second electroconductive member 137 and disposed between the second electroconductive member 137 and the impurity semiconductor layer 134.

The electrode wire 14 and the first electroconductive member 136 are made of an Al film having a thickness of about 1 μm from the viewpoint of reducing the resistance. Other materials that can be used for the first electroconductive member 136 include metals having a specific resistance of less than 3.0 μΩ·cm at 300 K, such as Cu, and alloys mainly containing such a metal. In the description herein, metals having a specific resistance of less than 3.0 μΩ·cm and alloys mainly containing such a metal are referred to as low-resistance metals. Since low-resistance metals are not passive, they can be easily corroded by water or a remaining component of an etchant used in the manufacturing process. A passive metal refers to a metal in a state where the metal does not corrode even though it is under corroding conditions in a thermodynamic sense, and the corrosion of a metal means that the metal reacts with the environment in use and turns into a non-metal state from the surface, and is thus gradually lost. The low-resistance metal member may be provided with films of a metal such as Mo, Cr or Ti having a higher specific resistance than the low-resistance metal on and under the low-resistance metal member. These metal films are intended to prevent the resistive contact of Al or the like with other members and the diffusion of Al or the like, and are referred to as barrier layers or ohmic contact layers. Even in this structure, a non-passive metal is exposed at the side surfaces of the electrode wire 14 and first electroconductive member 136 that have been formed by etching. The electrode wire 14 and the first electroconductive member 136 can have a thickness of 0.5 to 1 μm in view of electric resistivity and the precision of film forming (depositing). The second electrode 125 and the second electroconductive member 137 are made of a transparent electroconductive oxide, such as ITO. Exemplary transparent electroconductive oxides include ZnO, SnO₂, and CuAlO₂, in addition to ITO. Transparent electroconductive oxides are passive, and therefore have higher corrosion resistances than the above-described low-resistance metals. Transparent electroconductive oxides can be deposited to form a film with a low hardness by sputtering, and this film can cover the first electroconductive member 136 with a higher coverage than an inorganic film deposited by CVD. By covering the first electroconductive member 136 made of a non-passive low-resistance metal with the second electroconductive member 137 made of a passive transparent electroconductive oxide, a first and a second main electrode 135 highly resistant to corrosion can be formed for the TFT 13. In order to reduce the amount of retreat of the transparent electroconductive oxide film by etching (side etching amount), the thickness of the transparent electroconductive oxide film is set to about 50 nm. In view of the aperture ratio of the photoelectric conversion element and the S/N ratio according to the aperture ratio, a plane-type detector requires that the photoelectric conversion element have an electrode widely covering the impurity semiconductor layer and having a high light transmittance, and that the TFT be as small as possible and have a high operation speed. In order to prepare a TFT having a high operation speed, it is important to increase the ratio of the channel width (W) to the channel length (L) (W/L ratio). For a small TFT having a high operation speed, accordingly, the channel length of the TFT is reduced. Thus, the thickness of the transparent electroconductive oxide film can be 100 nm or less depending on the W/L ratio to be provided in view of the operation speed provided by the TFT, the aperture ratio of the photoelectric conversion element. In addition, in view of the electric resistivity to be provided by the second electrode 125 of the photoelectric conversion element, the thickness of the transparent electroconductive oxide film can be 50 nm or more. Furthermore, the thicknesses of the second electrode 125 and the second electroconductive member 137 can be smaller than and 0.02 to 0.1 times those of the common electrode wire 14 and the first electroconductive member 136. By covering the first electroconductive member 136 with the second electroconductive member 137, the second electroconductive member 137 defines the end faces of the first and second main electrodes 135. Thus, the channel length of the TFT 13 is determined by the second electroconductive member 137 that has been etched with a reduced retreat amount, and hence the channel length of the TFT 13 can be reduced.

The photoelectric conversion element 12 and TFT 13 are covered with a protective layer 147.

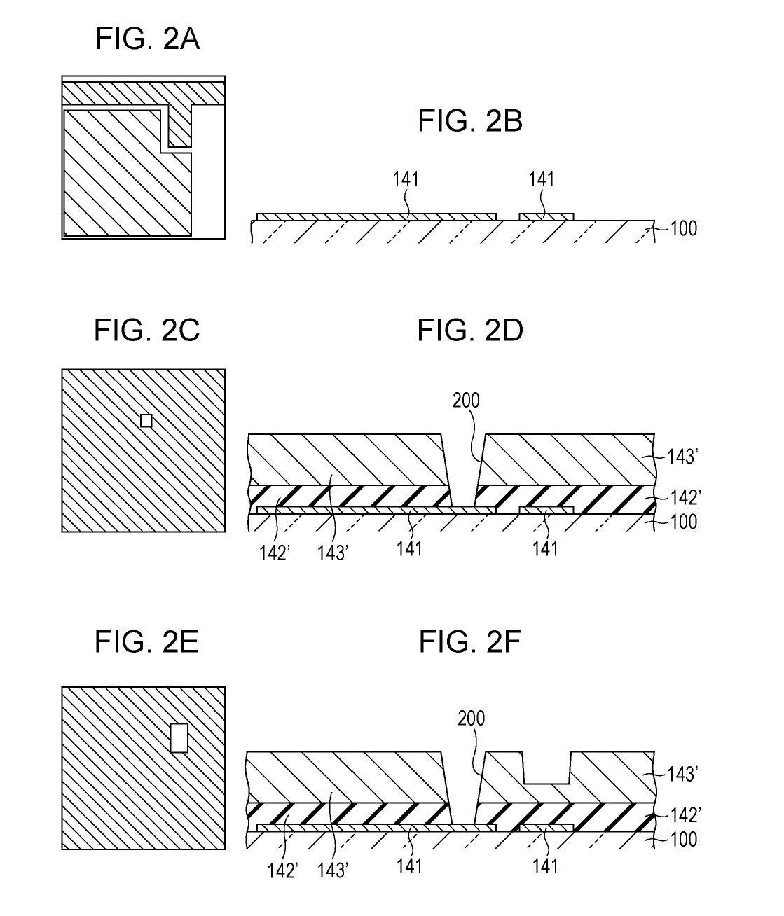

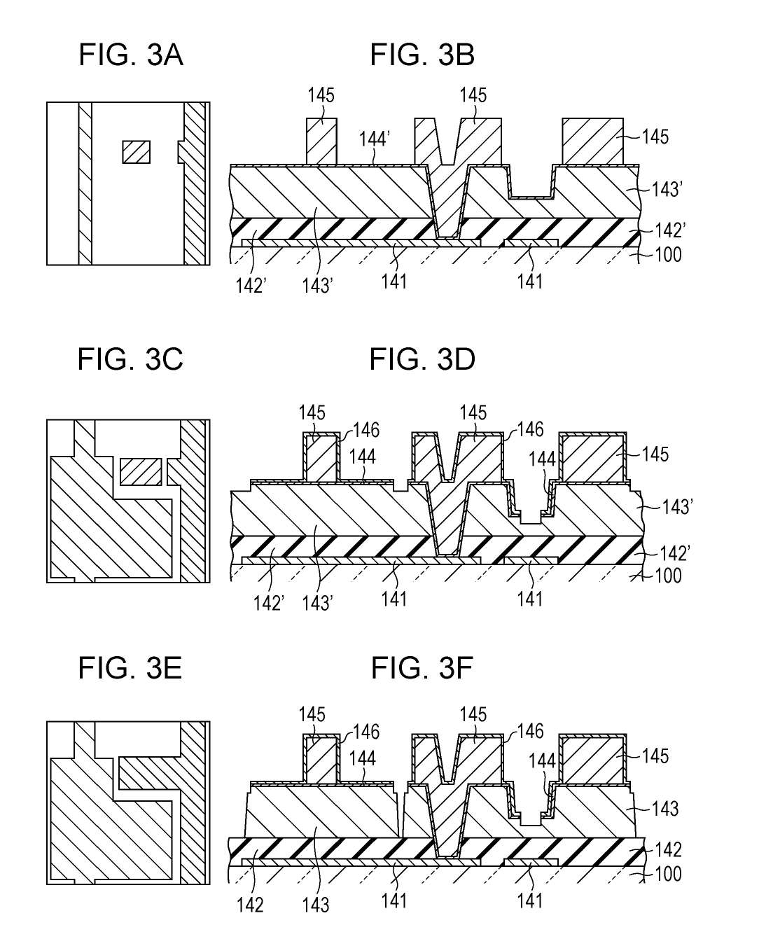

Turning now to FIGS. 2A to 3F, a method for manufacturing the detector according to the first embodiment will be described. FIGS. 2A, 2C, 2E, 3A, 3C and 3E are each a schematic plan view of the mask pattern of the photomask used in the corresponding step, and FIGS. 2B, 2D, 2F, 3B, 3D and 3F are each a sectional view in the corresponding step taken along a line corresponding to line A-A′ in FIG. 1A.

In the first step shown in FIGS. 2A and 2B, a first electroconductive film of, for example, Al, which will be formed into a first electroconductive layer 141, is deposited on an insulating substrate 100 by sputtering. Then, the first electroconductive film is etched into a first electroconductive layer 141 with a first mask shown in FIG. 2A. The first electroconductive layer 141 will act as the first electrode 121 and the control electrode 131, shown in FIG. 1B. In other words, the first electrode 121 and the control electrode 131 use the first electroconductive layer 141 formed from the same first electroconductive film. To use a layer formed from the same film means that different layers shaped by, for example, etching a film formed in a process are used.

Subsequently, in the second step shown in FIGS. 2C and 2D, an insulating film 142′ of silicon nitride or the like and a semiconductor film 143′ of amorphous silicon or the like are deposited over the insulating substrate 100 in that order so as to cover the first electroconductive layer 141 by plasma CVD. The insulating film 142′ and the semiconductor film 143′ are etched to form a contact hole 200 with a second mask shown in FIG. 2C. The insulating film 142′ will serve as the insulating layer 142, and the semiconductor film 143′ will serve as the semiconductor layer 143. In other words, the insulating layers 122 and 132 use the insulating layer 142 formed from the same insulating film 142′, and the semiconductor layers 123 and 133 use the semiconductor layer 143 formed from the same semiconductor film 143′.

Subsequently, in the third step shown in FIGS. 2E and 2F, the thickness of the semiconductor film 143′ in the region where the channel of the TFT 13 will be formed is reduced by dry etching with a third mask shown in FIG. 2E. Thus the on-resistance of the TFT 13 can be reduced.

Subsequently, in the fourth step shown in FIGS. 3A and 3B, an amorphous silicon film doped with a pentavalent element, such as phosphorus, is deposited as an impurity semiconductor film 144′ so as to cover the insulating film 142′ and the semiconductor film 143′ by plasma CVD. Although, in the present embodiment, the amorphous silicon film doped with a pentavalent element, such as phosphorus, is used as the impurity semiconductor film 144′, the dopant is not limited to pentavalent elements. For example, the impurity semiconductor film 144′ may be an amorphous silicon film doped with an element that can exhibit the Hall effect, such as boron. Subsequently, a second electroconductive film that will serve as the second electroconductive layer 145 is formed so as to cover the impurity semiconductor film 144′ by sputtering using Al. The second electroconductive film 144′ can be deposited to a thickness of 0.5 to 1 μm in view of electric resistivity and precision in forming the film. In the present embodiment, the second electroconductive film 144′ is deposited to a thickness of 1 μm. A low-resistance metal can be suitably used as the material of the second electroconductive film 144′. The low-resistance metal film may be provided with films of a metal such as Mo, Cr or Ti having a higher specific resistance than the low-resistance metal or an alloy of these metals on and under the low-resistance metal film. The metal films having a higher specific resistance are intended to prevent the resistive contact of the low-resistance metal film with other members and the diffusion of the low-resistance metal. Then, the second electroconductive film is subjected to wet etching with a fourth mask shown in FIG. 3A to form the electrode wire 14 and a second electroconductive layer 145 that will act as the first electroconductive member 136 of the first and second main electrodes 135 of the TFT 13. In other words, the electrode wire 14 and the first electroconductive member 136 use the second electroconductive layer 145 formed of the same second electroconductive film. At this point, the impurity semiconductor film 144′ over the region of the semiconductor film that will act as the channel of the TFT 13 remains without being removed. The etchant used for the wet etching is a mixture prepared by adding nitric acid and acetic acid to phosphoric acid, and the wet etching is isotropic. The fourth step allows the simultaneous formation of the electrode wire 14 and the first electroconductive member 136 of the first and second main electrodes 135 of the TFT 13 using the same fourth mask. Thus, the increase in the number of masks and the number of steps can be prevented.

Subsequently, in the fifth step shown in FIGS. 3C and 3D, a transparent electroconductive oxide film is deposited as a film of a transparent electroconductive oxide such as ITO so as to cover the impurity semiconductor film 144′ and the second electroconductive layer 145 by sputtering. The transparent electroconductive oxide film will serve as a third electroconductive layer 146. The thickness of the transparent electroconductive oxide film can be 100 nm or less in view of the operation speed to be provided by the TFT and the aperture ratio of the photoelectric conversion element. In addition, in view of the electric resistivity to be provided by the second electrode 125 of the photoelectric conversion element, the thickness of the transparent conductive oxide film can be 50 nm or more. Since the thickness of the transparent electroconductive oxide film is 50 to 100 nm, it can be smaller than and 0.02 to 0.1 times the thickness of the second electroconductive layer 145. In the present embodiment, the transparent electroconductive oxide film is deposited to a thickness of 50 nm. Subsequently, the transparent electroconductive oxide film is subjected to wet etching with a fifth mask shown in FIG. 3D, different from the fourth mask, to form the second electrode 125 of the photoelectric conversion element 12 and a third electroconductive layer 146 that will act as the second electroconductive member 137 of the first and second main electrodes 135 of the TFT 13. In other words, the second electrode 125 and the second electroconductive member 137 use the third electroconductive layer 146 formed from the same transparent electroconductive oxide film. The etchant used for this wet etching is a mixture of hydrochloric acid and nitric acid, and the wet etching is isotropic. Then, the impurity semiconductor film 144′ and part of the semiconductor film 143′ are continuously etched with the fifth mask in a dry process. Thus, an impurity semiconductor layer 144 that will act as the impurity semiconductor layers 124 and 134, and the third electroconductive layer 146 are successively formed with the same fifth mask. Hence, the impurity semiconductor layers 124 and 134 use the impurity semiconductor layer 144 formed from the same impurity semiconductor film 144′. The fifth step simultaneously forms the aperture of the photoelectric conversion element 12 defined by the second electrode 125 and the impurity semiconductor layer 124, and the channel of the TFT 13 with the same fifth mask, without considerably increasing the number of masks and number of steps. Also, the impurity semiconductor film 144′ over the region of the semiconductor layer that will act as the channel of the TFT 13 is removed in the fifth step. The fifth step can simultaneously form a second electrode 125 capable of uniformly applying a bias to the entirety of the photoelectric conversion element and having a high light transmittance, and a corrosion-resistant first and second main electrode, with the same fifth mask. The channel of the TFT 13 formed in the fifth step is defined by the third electroconductive layer 146 formed by etching the transparent electroconductive oxide film that has a smaller thickness than the second electroconductive layer 145 and is not easily retreated by etching. Therefore, it becomes easy to form a channel with a reduced channel length, and a TFT having a high operation speed and a large W/L ratio can be easily formed. Subsequently, in the sixth step shown in FIGS. 3E and 3F, undesired portions of the semiconductor film 143′ and insulating film 142′ are removed for element isolation by etching with a sixth mask shown in FIG. 3E. Thus, a semiconductor layer 143 that will act as the semiconductor layer 123 of the photoelectric conversion element 12 and the semiconductor layer 133 of the TFT 13, the insulating layer 122 of the photoelectric conversion element, and the insulating layer 132 of the TFT 13 are formed.

Then, a protective layer 147 is formed so as to cover the photoelectric conversion element 12 and the TFT 13. Thus, the structure shown in FIG. 1B is formed in a common manufacturing process.

The second electroconductive layer 145 formed in the above process is completely covered with the third electroconductive layer 146. Since the third electroconductive layer 146 is made of a corrosion-resistant transparent electroconductive oxide, such as ITO, the protective layer 147 need not cover the entire surfaces of the photoelectric conversion element 12 and the TFT 13. The protective layer 147 may be formed of an inorganic insulating film by CVD to such a thickness as can cover the side walls of the semiconductor layer 143 and impurity semiconductor layer 144 and the region of the semiconductor layer 143 that will act as the channel, for example, a thickness of 200 nm, smaller than the thickness of the second electroconductive layer 145. Alternatively, an organic insulating film that has a lower corrosion resistance but can be formed to a larger thickness, than the inorganic insulating film may be used for the protective layer 147, instead of the inorganic insulating film.

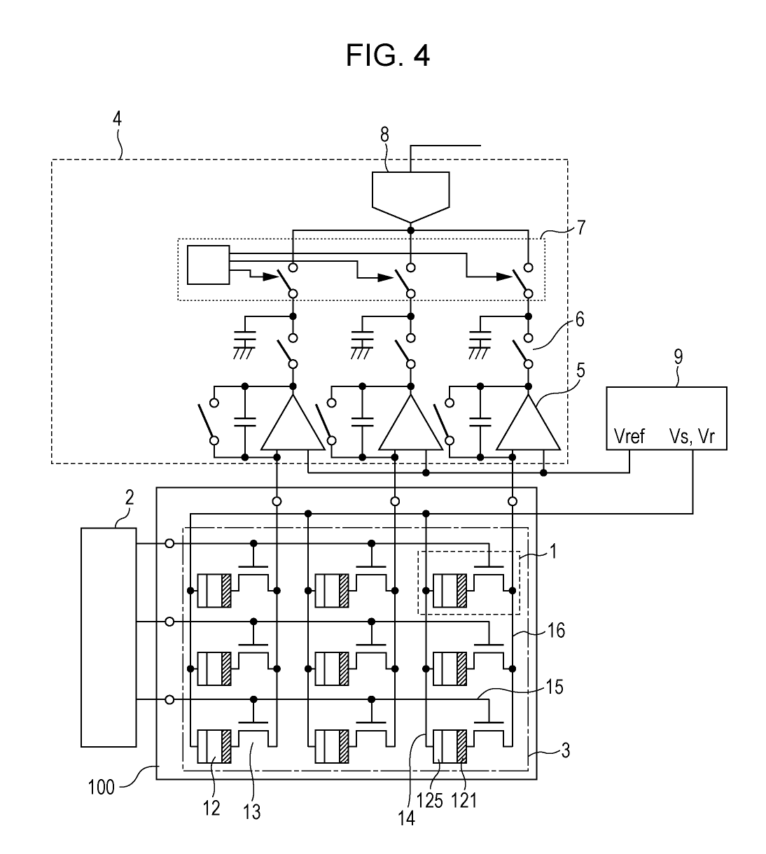

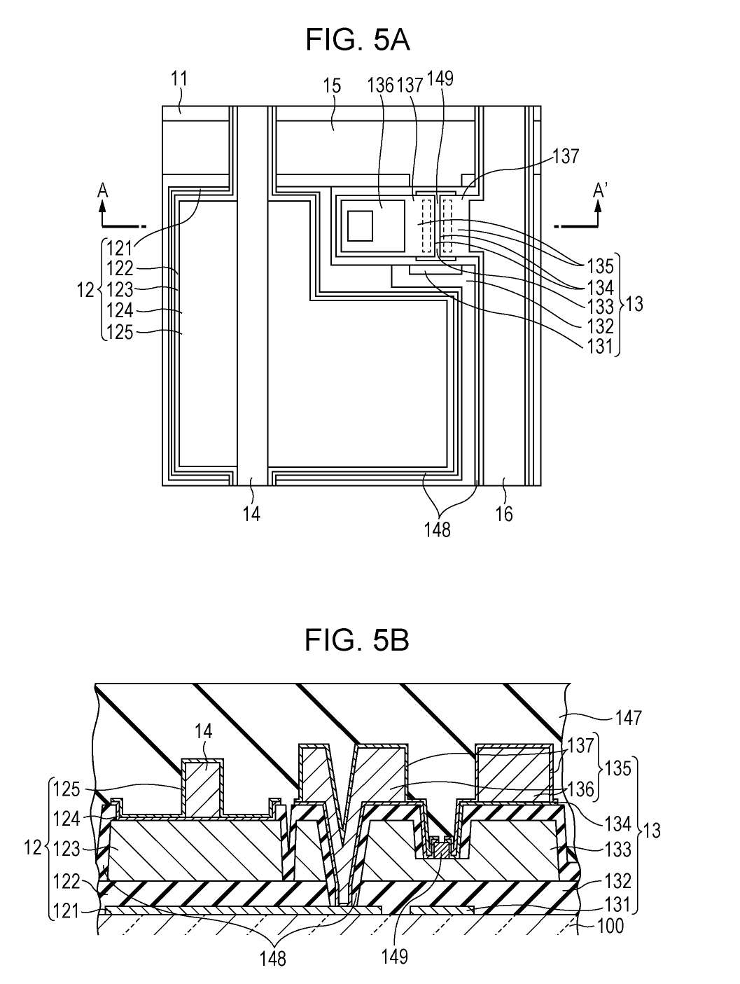

The equivalent circuit of a radiation detection apparatus according to the first embodiment of the invention will now be described with reference to the schematic diagram shown in FIG. 4. Although FIG. 4 shows a 3-by-3 equivalent circuit diagram for the sake of simple description, the equivalent circuit according to aspects of the invention is not limited to this arrangement, and the radiation detection apparatus can have an n-by-m pixel array (n and m are each a natural number of two or more) without particular limitation. The detector according to the present embodiment includes a photoelectric conversion portion 3 on the surface of a substrate 100. The photoelectric conversion portion 3 includes a plurality of pixels arranged in the row and column directions. Each pixel 1 includes a photoelectric conversion element 12 that converts radiation or light into a charge, and a TFT 13 that outputs electrical signals according to the charge of the photoelectric conversion element 12. A scintillator (not shown) that converts radiation into a visible light having a wavelength that can be sensed by the photoelectric conversion element is disposed on the surface (first surface), adjacent to the second electrode 125 of the photoelectric conversion element, of the photoelectric conversion portion 3. Electrode wires 14 are each connected to the second electrodes 125 of the photoelectric conversion elements 12 in the same column of the arrangement. Control lines 15 are each connected to the control electrodes 131 of the TFTs 13 in the same row of the arrangement, and electrically connected to a driving circuit 2. By applying driving pulses to the control lines 15 arranged in the column direction one after another or simultaneously, electrical signals are outputted in parallel by the row from the pixels to signal lines 16 arranged in the row direction. The signal lines 16 are each connected to the second main electrodes 136 of the TFTs 13 in the same column of the arrangement, and electrically connected to a read circuit 4. The read circuit 4 includes, for each signal line 16, an integrating amplifier 5 that integrates and amplifies electrical signals from the signal line 16, and a sample hold circuit 6 that samples and holds the electrical signal amplified in and outputted from the integrating amplifier 5. The read circuit 4 further includes a multiplexer 7 that transforms electrical signals outputted in parallel from the sample hold circuits into an in-series electrical signal, and an A/D converter 8 that converts the outputted electrical signal into digital data. A reference potential Vref is supplied to the non-inverted input terminals of the integrating amplifiers 5 from a power supply circuit 9. The power supply circuit 9 is electrically connected to the electrode wires 14 arranged in the row direction, and supplies a bias potential Vs or an initialization potential Vr to the second electrodes 125 of the photoelectric conversion elements 12.

The operation of the radiation detection apparatus of the present embodiment will be described below. A reference potential Vref is applied to the first electrode 121 of the photoelectric conversion element 12 through the TFT 13, and a bias potential Vs is applied to the second electrode 125. Thus, a bias that can deplete the semiconductor layer 123 is applied to the photoelectric conversion element 12. In this state, the radiation emitted to a test subject is transmitted through the subject while being attenuated and is converted into visible light by the scintillator. The visible light enters the photoelectric conversion element 12 and is converted into a charge. When the TFT 13 is brought into electrical continuity by driving pulses applied to the control line 15 from the driving circuit 2, an electrical signal according to the charge is outputted to the signal line 16, and read outside as digital data by the read circuit 4. Then, positive carriers generated and remaining in the photoelectric conversion element 12 are removed by converting the potential of the common electrode wire 14 from a bias potential Vs to an initialization potential Vr and bring the TFT 13 into electrical continuity. Then, the photoelectric conversion element 12 is initialized by converting the potential of the common electrode wire 14 from an initialization potential Vr to a bias potential Vs and bringing the TFT 13 into electrical continuity.

Although the present embodiment has described a structure in which the control electrode 131 is electrically connected to the control line 15 and one of the first and second main electrodes 135 is electrically connected to the first electrode 121 of the photoelectric conversion element 12, the invention is not limited to this structure. For example, one of the first and second main electrodes 135 may be electrically connected to the electrode wire 14 in each pixel, and the first electrode 121 may be common to the photoelectric conversion elements 121. In this instance, the contact hole described with reference to FIG. 2C is not necessary.

The structure of the pixel of a detector according to a second embodiment of the invention will now be described with reference to FIGS. 5A and 5B. FIG. 5A is a plan view of a pixel of the detector, and FIG. 5B is a sectional view taken along line A-A′ in FIG. 5A. The same parts as in the first embodiment are designated by the same reference numerals, and thus description thereof is omitted.

The detector of the present embodiment includes an interlayer insulating layer 148 covering the side walls of the semiconductor layer 123 of the photoelectric conversion element 12 and the semiconductor layer 133 of the TFT 13, and an etch stop layer 149 covering the region of the semiconductor layer 133 that will act as the channel of the TFT 13, in addition to the structure of the first embodiment. This structure enhances the water resistance of the side walls of the photoelectric conversion element 12 and TFT 13. In addition, since two insulating layers are provided between the control line 15 and the signal line 16, the parasitic capacitance applied to the signal line 16 can be reduced, and thus noise can be reduced.

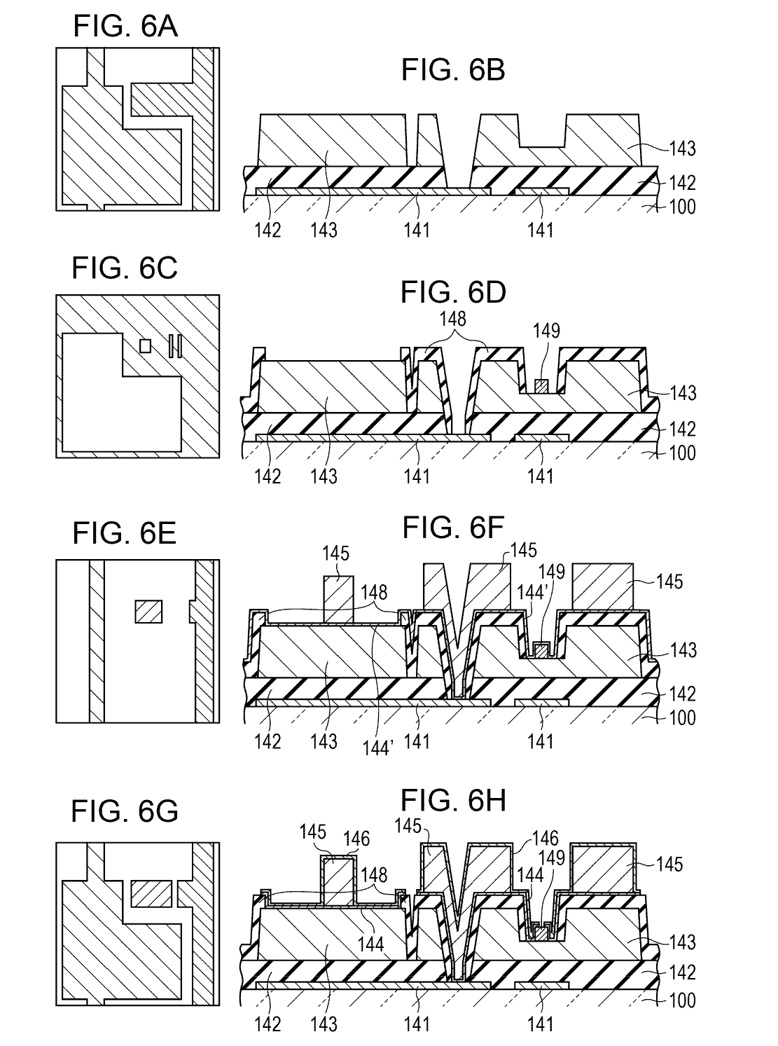

Turning now to FIGS. 6A to 6H, a method for manufacturing the detector according to the second embodiment will be described. FIGS. 6A, 6C, 6E and 6G are each a schematic plan view of the mask pattern of the photomask used in the corresponding step, and FIGS. 6B, 6D, 6F and 6H are each a sectional view in the corresponding step taken along a line corresponding line A-A′ in FIG. 5A. The first to third steps are the same as in the first embodiment, and thus description thereof is omitted.

In the fourth step shown in FIGS. 6A and 6B, undesired portions of the semiconductor film 143′ and insulating film 142′ are removed for element isolation by etching with a fourth mask shown in FIG. 6A. Thus, a semiconductor layer 143 that will act as the semiconductor layer 123 of the photoelectric conversion element 12 and the semiconductor layer 133 of the TFT 13, the insulating layer 122 of the photoelectric conversion element, and the insulating layer 132 of the TFT 13 are formed.

Subsequently, in the fifth step shown in FIGS. 6C and 6D, an interlayer insulating film, such as a silicon nitride film, that will act as the interlayer insulating layer 148 and the etch stop layer 149 is deposited over the insulating substrate 100 so as to cover the semiconductor layer 143 by plasma CVD. The interlayer insulating layer 148 and the etch stop layer 149 are formed by etching the silicon nitride film with a fifth mask shown in FIG. 6D.

Subsequently, in the sixth step shown in FIGS. 6E and 6F, an impurity semiconductor film 144′ that will act as the impurity semiconductor layer 144 is deposited so as to cover the insulating layer 142, the semiconductor layer 143, the interlayer insulating layer 148, and the etch stop layer 149 by plasma CVD. Subsequently, a second electroconductive film that will act as the second electroconductive layer 145 is deposited so as to cover the impurity semiconductor film 144′ by sputtering using Al. In the present embodiment, this second electroconductive film is deposited to a thickness of 1 μm. Then, the second electroconductive film is subjected to wet etching with a sixth mask shown in FIG. 6E to form the electrode wire 14 and the second electroconductive layer 145 that will act as the first electroconductive member 136 of the first and second main electrodes of the TFT 13. In other words, the electrode wire 14 and the first electroconductive member 136 use the second electroconductive layer 145 formed of the same second electroconductive film. At this point, the impurity semiconductor film 144′ over the region of the semiconductor film that will act as the channel of the TFT 13 remains without being removed. The etchant used for the wet etching is a mixture prepared by adding nitric acid and acetic acid to phosphoric acid, and the wet etching is isotropic. The sixth step allows the simultaneous formation of the electrode wire 14 and the first electroconductive member 136 of the first and second main electrodes 135 of the TFT 13 using the same sixth mask. Thus, the increase in the number of masks and the number of steps can be prevented.

Subsequently, in the seventh step shown in FIGS. 6G and 6H, a transparent electroconductive oxide film is deposited as a film of ITO or the like so as to cover the impurity semiconductor film 144′ and the second electroconductive layer 145 by sputtering. The transparent electroconductive oxide film will act as a third electroconductive layer 146. In the present embodiment, the transparent electroconductive oxide film is deposited to a thickness of 50 nm. Subsequently, the transparent electroconductive oxide film is subjected to wet etching with a seventh mask shown in FIG. 6G, different from the sixth mask, to form the second electrode 125 of the photoelectric conversion element 12 and the third electroconductive layer 146 that will act as the second electroconductive member 137 of the first and second main electrodes 135 of the TFT 13. In other words, the second electrode 125 and the second electroconductive member 137 use the third electroconductive layer 146 formed from the same transparent electroconductive oxide film. The etchant used for this wet etching is a mixture of hydrochloric acid and nitric acid, and the wet etching is isotropic. Then, the impurity semiconductor film 144′ and part of the semiconductor layer 143 are continuously etched with the seventh mask in a dry process. Thus, an impurity semiconductor layer 144 that will act as the impurity semiconductor layers 124 and 134, and the third electroconductive layer 146 are successively formed with the same fifth mask. The seventh step simultaneously forms the aperture of the photoelectric conversion element 12 defined by the second electrode 125 and the impurity semiconductor layer 124, and the channel of the TFT 13 with the same seventh mask, without considerably increasing the number of masks and number of steps. Also, the impurity semiconductor film over the region of the semiconductor layer 143 that will act as the channel of the TFT 13 is removed in the seventh step. The seventh step can simultaneously form a second electrode 125 capable of uniformly applying a bias to the entirety of the photoelectric conversion element and having a high light transmittance, and a corrosion-resistant first and second main electrode through the same seventh mask. The channel of the TFT 13 formed in the seventh step is defined by the third electroconductive layer 146 formed by etching the transparent electroconductive oxide film that has a smaller thickness than the second electroconductive layer 145 and is not easily retreated by etching. Therefore, it becomes easy to form a channel with a reduced channel length, and a TFT having a high operation speed and a large W/L ratio can be easily formed. The surface and the side surface of the semiconductor layer 123 are covered with the interlayer insulating layer 148 and the third electroconductive layer 146. Thus, the side wall of the semiconductor layer 123 is not exposed to etchant used for etching, and consequently, leakage current in the side wall of the semiconductor layer 123 can be prevented. The surface and the side surface of the semiconductor layer 133 are covered with the interlayer insulating layer 148, the third electroconductive layer 145 and the etch stop layer 149. In particular, the region of the semiconductor layer 133 that will act as the channel of the TFT 13 is covered with the third electroconductive layer 145 and the etch stop layer 149. Thus, the region of the semiconductor layer 133 that will act as the channel of the TFT 13 is not exposed to etchant used for etching, and consequently, leakage current in the channel of the TFT 13 can be reduced.

Then, a protective layer 147 is formed so as to cover the photoelectric conversion element 12 and the TFT 13. Thus, the structure shown in FIG. 5B is formed in a common manufacturing process. In the present embodiment, the protective layer 147 is formed of an organic insulating film that can be easily formed to a large thickness of 4 to 6 μm. The protective layer 147 provides an even surface, and a scintillator (not shown) having a columnar crystal structure of, for example, CsI, can be formed on the even surface by deposition. The same applies to the first embodiment.

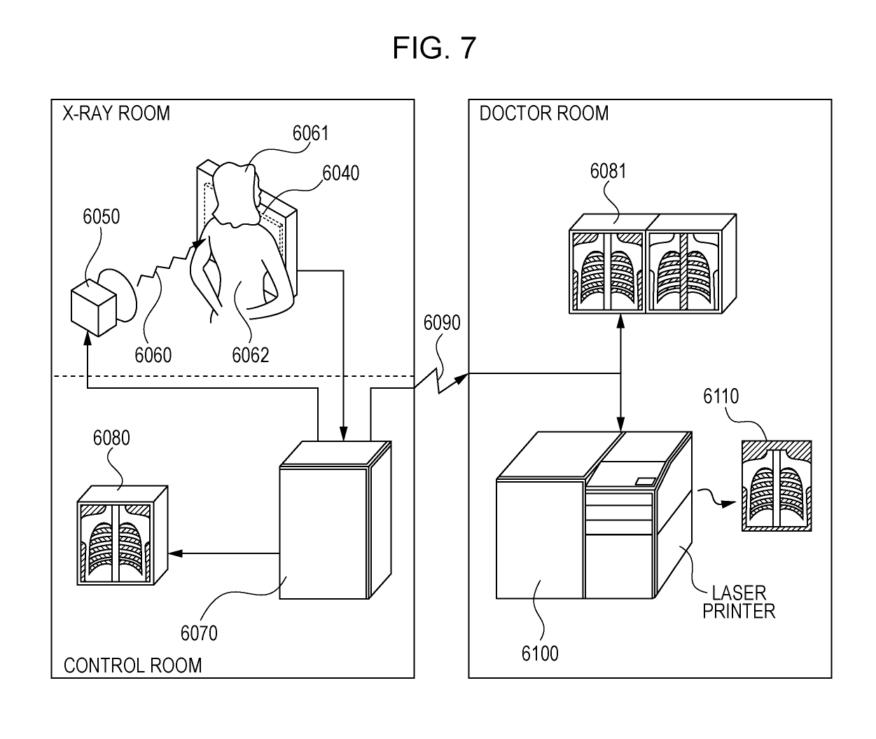

A radiation detection system including the detector of an embodiment of the invention will now be described with reference to FIG. 7.

An X ray 6060 generated from an X-ray tube 6050, or radiation source, penetrates the chest 6062 of a patient or test subject 6061 and enters the radiation detection apparatus 6040 in which a scintillator is disposed above the photoelectric conversion elements 12 in the photoelectric conversion portion 3. The incident X ray includes information of the interior of the patient's body. The scintillator emits light corresponding to the incidence of the X ray. The light is converted into electrical signals in the photoelectric conversion portion 3, and thus electrical information is produced. This information is converted into digital signals, and is then image-processed by an image processor 6070, which is a signal processing device. Thus, the information can be observed on a display 6080 that is a display unit in a control room.

In addition, the patient's information can be transmitted to a remote place through a transmission device, such as a telephone line 6090, and thus can be displayed on a display 6081 that is a display unit or stored in a recording device such as an optical disk, in a doctor room or the like in another place. Thus, the system allows doctors in remote places to diagnose. The information can be stored in a film 6110 that is a recording medium by a film processor 6100 used as a recording device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-092151 filed Apr. 18, 2011, which is hereby incorporated by reference herein in its entirety.

What is claimed is:

1. A method for manufacturing a detector including a photoelectric conversion element that includes on a substrate, in this order from the substrate, a first electrode, an insulating layer, a semiconductor layer, an impurity semiconductor layer, and a second electrode to which an electrode wire is electrically connected, and a thin film transistor that includes on the substrate, in this order from the substrate, a control electrode, an insulating layer, a semiconductor layer, an impurity semiconductor layer, and a first and a second main electrode including a first electroconductive member and a second electroconductive member, the method comprising:
the first step of depositing a second electroconductive film containing a non-passive metal over the substrate so as to cover an impurity semiconductor film, and forming the first electroconductive member of the first and second main electrodes and the electrode wire from the second electroconductive film; and
the second step of depositing a transparent electroconductive oxide film over the substrate so as to cover the impurity semiconductor film, the electrode wire and the first electroconductive member after the first step, forming the second electroconductive member of the first and second main electrodes and the second electrode from the transparent electroconductive oxide film, and forming the impurity semiconductor layer of the thin film transistor and the impurity semiconductor layer of the photoelectric conversion element from the impurity semiconductor film,
wherein the second electroconductive member, the second electrode, the impurity semiconductor layer of the thin film transistor and the impurity semiconductor layer of the photoelectric conversion element are formed with the same mask in the second step, and wherein the first electroconductive member and the electrode wire are formed with another mask in the first step.

2. The method according to claim 1, further comprising a step of depositing a semiconductor film before the depositing of the impurity semiconductor film, and the step of forming a contact hole in the insulating film and the semiconductor film between the depositing of the semiconductor film and the depositing of the impurity semiconductor film.

3. The method according to claim 2, further comprising the step of forming the semiconductor layer of the photoelectric conversion element and the semiconductor layer of the thin film transistor from the semiconductor film after the forming the contact hole.

4. The method according to claim 2, further comprising between the forming of the contact hole and the forming of the impurity semiconductor film the steps of:
forming the semiconductor layer of the photoelectric conversion element and the semiconductor layer of the thin film transistor from the semiconductor film; and
forming an interlayer insulating layer covering the side surface of the semiconductor layer of the photoelectric conversion element and the side surface of the semiconductor layer of the thin film transistor, and an etch stop layer covering the region of the semiconductor layer that will act as a channel of the thin film transistor, from an interlayer insulating film depositing so as to cover the semiconductor layer of the photoelectric conversion element and the semiconductor layer of the thin film transistor.

5. The method according to claim 1, wherein the transparent electroconductive oxide film is deposited to a smaller thickness than the second electroconductive film.

6. The method according to claim 5, wherein the second electroconductive film is deposited to a thickness of 0.5 to 1 μm, and the transparent electroconductive oxide film is formed to a thickness of 50 to 100 nm.

7. A radiation detection apparatus comprising:
a detector manufactured by the method as set forth in claim 1; and
a scintillator disposed above the photoelectric conversion element of the detector.

8. A radiation detection system comprising:
the radiation detection apparatus as set forth in claim 7;
a signal processing device that processes a signal from the radiation detection apparatus;
a recording device that records the signal from the signal processing device;
a display unit on which the signal from the signal processing device is displayed; and
a transmission device that transmits the signal from the signal processing device.

9. A method for manufacturing a detector including a photoelectric conversion element that includes on a substrate, in this order from the substrate, a first electrode, an insulating layer, a semiconductor layer, an impurity semiconductor layer, and a second electrode to which an electrode wire is electrically connected, and a thin film transistor that includes on the substrate, in this order from the substrate, a control electrode, an insulating layer, a semiconductor layer, an impurity semiconductor layer, and a first and a second main electrode including a first electroconductive member and a second electroconductive member, the method comprising:
the first step of forming the first electrode and the control electrode from a first electroconductive film deposited on the substrate with a first mask;
the second step of depositing an insulating film and a semiconductor film in that order over the substrate so as to cover the first electrode and the control electrode;
the third step of depositing an impurity semiconductor film and a second electroconductive film containing a non-passive metal, in that order, over the substrate so as to cover the semiconductor film, and forming the electrode wire and the first electroconductive member of the first and second main electrodes from the second electroconductive film with a second mask;
the fourth step of depositing a transparent electroconductive oxide film over the substrate so as to cover the impurity semiconductor film, the electrode wire and the first electroconductive member;
the fifth step of forming with a third mask the second electroconductive member of the first and second main electrodes and the second electrode from the transparent electroconductive oxide film, and the impurity semiconductor layer of the thin film transistor and the impurity semiconductor layer of the photoelectric conversion element from the impurity semiconductor film; and
the sixth step of forming the semiconductor layer of the photoelectric conversion element and the semiconductor layer of the thin film transistor from the semiconductor film with a fourth mask after the fifth step.

10. The method according to claim 9, further comprising the step of forming a contact hole in the insulating film and the semiconductor film between the second step and the third step.

11. The method according to claim 9, wherein the transparent electroconductive oxide film is deposited to a smaller thickness than the second electroconductive film.

12. The method according to claim 11, wherein the second electroconductive film is deposited to a thickness of 0.5 to 1 μm, and the transparent electroconductive oxide film is formed to a thickness of 50 to 100 nm.

13. A radiation detection apparatus comprising:
a detector manufactured by the method as set forth in claim 9; and
a scintillator disposed above the photoelectric conversion element of the detector.

14. A radiation detection system comprising:
the radiation detection apparatus as set forth in claim 13;
a signal processing device that processes a signal from the radiation detection apparatus;
a recording device that records the signal from the signal processing apparatus;
a display unit on which the signal from the signal processing device is displayed; and
a transmission device that transmits the signal from the signal processing device.

15. A method for manufacturing a detector including a photoelectric conversion element that includes on a substrate, in this order from the substrate, a first electrode, an insulating layer, a semiconductor layer, an impurity semiconductor layer, and a second electrode to which an electrode wire is electrically connected, and a thin film transistor that includes on the substrate, in this order from the substrate, a control electrode, an insulating layer, a semiconductor layer, an impurity semiconductor layer, and a first and a second main electrode including a first electroconductive member and a second electroconductive member, the method comprising:
the first step of forming the first electrode and the control electrode from a first electroconductive film deposited on the substrate through a first mask;
the second step of depositing an insulating film and a semiconductor film in that order over the substrate so as to cover the first electrode and the control electrode;
the third step of forming the semiconductor layer of the photoelectric conversion element and the semiconductor layer of the thin film transistor from the semiconductor film with a second mask;
the fourth step of forming an interlayer insulating layer covering the side surface of the semiconductor layer of the photoelectric conversion element and the side surface of the semiconductor layer of the thin film transistor, and an etch stop layer covering the region of the thin film transistor that will act as a channel of the thin film transistor, with a third mask from an interlayer insulating film deposited over the substrate so as to cover the semiconductor layer of the photoelectric conversion element and the semiconductor layer of the thin film transistor;
the fifth step of depositing an impurity semiconductor film and a second electroconductive film containing a non-passive metal in that order over the substrate so as to cover the semiconductor layer of the photoelectric conversion element, the semiconductor layer of the thin film transistor, the interlayer insulating layer and the etch stop layer, and forming the electrode wire and the first electroconductive member of the first and second main electrodes from the second electroconductive film with a fourth mask;
the sixth step of depositing a transparent electroconductive oxide film over the substrate so as to cover the impurity semiconductor film, the electrode wire and the first electroconductive member; and
the seventh step of forming with a fifth mask the second electroconductive member of the first and second main electrodes and the second electrode from the transparent electroconductive oxide film, and the impurity semiconductor layer of the thin film transistor and the impurity semiconductor layer of the photoelectric conversion element from the impurity semiconductor film.

16. The method according to claim 15, further comprising the step of forming a contact hole in the insulating film and the semiconductor film between the second step and the third step.

17. The method according to claim 15, wherein the transparent electroconductive oxide film is deposited to a smaller thickness than the second electroconductive film.

18. The method according to claim 17, wherein the second electroconductive film is deposited to a thickness of 0.5 to 1 μm, and the transparent electroconductive oxide film is formed to a thickness of 50 to 100 nm.

19. A radiation detection apparatus comprising:
a detector manufactured by the method as set forth in claim 15; and
a scintillator disposed above the photoelectric conversion element of the detector.

20. A radiation detection system comprising:
the radiation detection apparatus as set forth in claim 19;
a signal processing device that processes a signal from the radiation detection apparatus;
a recording device that records the signal from the signal processing apparatus;
a display unit on which the signal from the signal processing device is displayed; and
a transmission device that transmits the signal from the signal processing device.
